(19) United States
(12) Patent Application Publication
(10) Pub. No.: US 2021/0313380 A1
(43) Pub. Date: Oct. 7, 2021

(54) PHOTOELECTRIC CONVERSION DEVICE AND MANUFACTURING METHOD THEREFOR

(71) Applicant: CANON KABUSHIKI KAISHA, Tokyo (JP)

(72) Inventor: Kosei Uehira, Tokyo (JP)

(21) Appl. No.: 17/212,099

(22) Filed: Mar. 25, 2021

(30) Foreign Application Priority Data
Apr. 1, 2020 (JP) 2020-065792

(51) Int. Cl. H01L 27/146

(52) U.S. Cl. CPC H01L 27/14643; H01L 27/14689; H01L 27/1464; H01L 27/14685; H01L 27/14641; H01L 27/1462

(57) ABSTRACT

A photoelectric conversion device having a wiring layer on an opposite side of a semiconductor substrate to a light receptive surface thereof includes a semiconductor substrate having a trench part on a side of the light receptive surface, a first metal oxide film arranged at the light receptive surface of the semiconductor substrate, and a second metal oxide film arranged at a side surface of the trench part and having a film thickness larger than that of the first metal oxide film.

### BACKGROUND OF THE INVENTION

### Field of the Invention

The present invention relates to a photoelectric conversion device and a manufacturing method therefor.

### Description of the Related Art

A solid-state image pickup element (photoelectric conversion device) has pixels arranged in an array. A solid-state image pickup element having wiring on the side opposed to the light receptive surface is called a back side illumination type solid-state image pickup element.

WO 2013/111628 discloses a solid-state image pickup element in which a trench is formed between pixels. The trench is disposed on the light receptive surface (back surface) side. For this reason, this structure is called a back side trench structure. The back side trench structure can suppress color mixture, i.e., one of problems of the back side illumination type solid-state image pickup element.

WO 2013/111628 further discloses formation of a metal oxide film in the trench.

### SUMMARY OF THE INVENTION

According to the first aspect of the present invention, it is arranged a photoelectric conversion device having a wiring layer on an opposite side of a semiconductor substrate to a light receptive surface thereof, the device including a semiconductor substrate having a trench part on a side of the light receptive surface, a first metal oxide film arranged at the light receptive surface of the semiconductor substrate, and a second metal oxide film arranged at a side surface of the trench part and having a film thickness larger than that of the first metal oxide film.

According to the second aspect of the present invention, it is arranged a photoelectric conversion device having a wiring layer on an opposite side of a semiconductor substrate to a light receptive surface thereof, the device including a semiconductor substrate having a trench part on a side of the light receptive surface, a first metal oxide film arranged at the light receptive surface of the semiconductor substrate, and a second metal oxide film embedded in the trench part, wherein a width of the trench part is larger than twice a film thickness of the first metal oxide film.

According to the third aspect of the present invention, it is provided a manufacturing method for a photoelectric conversion device, the method including a trench forming step of forming a trench part at a first surface of a semiconductor substrate, a first deposition step of depositing a metal oxide film at the first surface, and a side surface of the trench part of the semiconductor substrate, a thinning step of thinning the first surface of the semiconductor substrate after the first deposition step, and a second deposition step of depositing a metal oxide film at least on the first surface of the semiconductor substrate after the thinning step.

Further features of the present invention will become apparent from the following description of exemplary embodiments with reference to the attached drawings.

### BRIEF DESCRIPTION OF THE DRAWINGS

FIGS. 1A and 1B are schematic views of a solid-state image pickup element in accordance with Embodiment 1;

FIGS. 2A and 2B are schematic views of a solid-state image pickup element in accordance with Comparative Example 1;

FIGS. 3A and 3B are schematic views of a solid-state image pickup element in accordance with Comparative Example 2;

FIGS. 4A and 4B are schematic views of a solid-state image pickup element in accordance with Comparative Example 3;

FIGS. 5A to 5C are explanatory views of the definition of the film thickness of a metal oxide film;

FIG. 6 is a process flowchart showing a method for manufacturing a solid-state image pickup element in accordance with Embodiment 1;

FIGS. 7A to 7F are cross sectional views of each manufacturing step;

FIGS. 8A to 8G are cross sectional views of each manufacturing step;

FIGS. 9A and 9B are cross sectional schematic views of a back side trench after CMP;

FIGS. 10A and 10B are views for comparing solid-state image pickup elements in accordance with Embodiment and Comparative Example;

FIGS. 11A and 11B are correlation diagrams of the film thickness of an aluminum oxide film and the flat-band potential shift;

FIGS. 12A and 12B are hydrogen concentration distribution views obtained by subjecting the aluminum oxide film to SIMS analysis;

FIG. 13 is a correlation diagram of the film thickness of the aluminum oxide film and the light transmittance;

FIG. 14 is a block view of an imaging system in accordance with Embodiment 2; and

FIGS. 15A and 15B are block views of an imaging system and a mobile unit in accordance with Embodiment 3.

### DESCRIPTION OF THE EMBODIMENTS

With a photoelectric conversion device having a back side trench structure, undesirably, the dark current remarkably increases, and exceeds the required value, resulting in deterioration of the pixel performance.

In the present Embodiment, it is an object to provide a technology advantageous for suppressing the deterioration of the pixel performance in a photoelectric conversion device having a back side trench structure.

Before detailed description, the following five phenomena clarified as a result of the study conducted by the present inventors will be described.

(1) When the film thickness of a metal oxide film is large, the dark current is suppressed;
(2) When the film thickness of a metal oxide film is large, the hydrogen concentration is high;
(3) When the film thickness of a metal oxide film is large, the transmittance is low;
(4) Regarding the relationship between the area of the photodiode interface and the dark current; and
(5) The estimating method of the dark current
Below, the items will be described in detail one item by one item. Herein, a description will be given by taking an aluminum oxide film as an example of a metal oxide.

First, a description will be given to “(1) the phenomenon in which a large film thickness of a metal oxide film suppresses the dark current”.

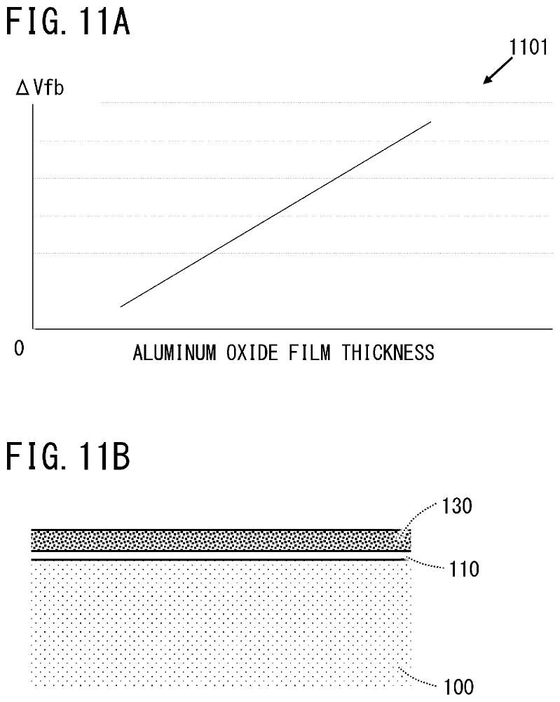

FIG. 11A is a graph 1101 showing the film thickness dependency of the shift ΔVfb of the flat band voltage when the film thickness of an aluminum oxide film 130 having a negative fixed electric charge is changed. The horizontal axis of the graph 1101 is the film thickness of the aluminum oxide film 130, and the vertical axis is the flat band voltage shift.

FIG. 11B shows the structure of a sample 1102 used in the measurement. The sample 1102 includes a silicon photodiode 100 (which will be hereinafter abbreviated as photodiode), a silicon oxide film 110, and an aluminum oxide film 130 stacked in this order. An about 50-A thick silicon oxide film 110 naturally formed is interposed between the photodiode 100 and the aluminum oxide film 130.

As indicated from FIG. 11A, an increase in aluminum oxide film thickness increases the value of ΔVfb in the positive direction. This indicates that the dark current generated at the interface of the photodiode 100 is confined to the electric field of the fixed electric charges of the aluminum oxide film 130 (which is referred to as a pinning effect), and that the effect of suppressing the dark current generation of the photodiode 100 is high.

Secondly, a description will be given to “(2) the phenomenon in which a large film thickness of a metal oxide film results in a high hydrogen concentration”.

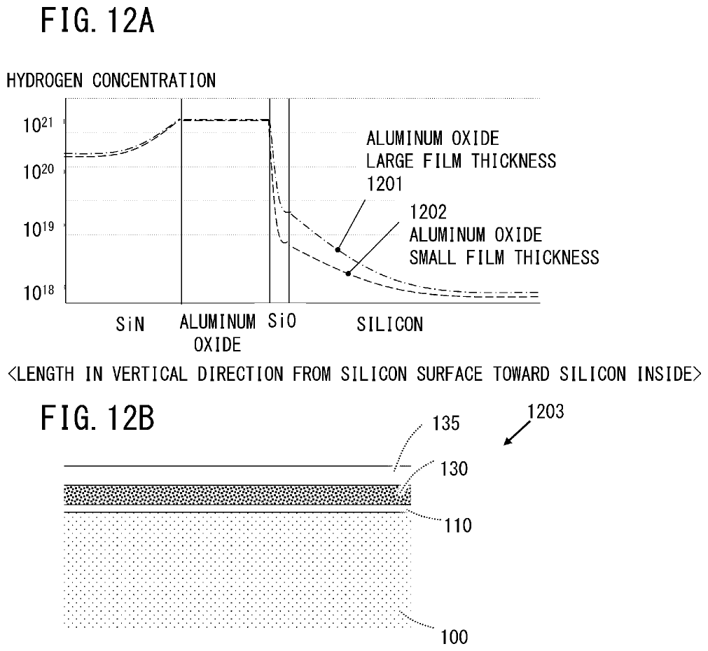

FIG. 12A shows the hydrogen concentrations obtained by performing SIMS analysis while digging in the depth direction with respect to two samples. A graph 1201 shows the hydrogen concentration of the sample in which the film thickness of the aluminum oxide film is large, and a graph 1202 shows the hydrogen concentration of the sample in which the small film thickness of the aluminum oxide film is small. The horizontal axis of the graph is the depth position, and the vertical axis is the hydrogen concentration.

FIG. 12B shows the film structure of a sample 1203 used in the hydrogen concentration measurement. The sample 1203 has a structure in which an insulation film 135 is formed at the uppermost part of the film structure of the sample 1102 shown in FIG. 11B. For the insulation film 135, silicon nitride was used. The difference between the two samples used in the measurement of FIG. 12A is the difference in film thickness of the aluminum oxide film 130.

As indicated from FIG. 12A, the hydrogen concentration inside silicon increases with an increase in film thickness of the aluminum oxide film 130. Further, when the hydrogen concentration is high, the surrounding dangling bonds of silicon are reduced, resulting in a decrease in dark current.

Thirdly, a description will be given to “(3) the phenomenon in which a large film thickness of a metal oxide film results in the reduction of the transmittance”.

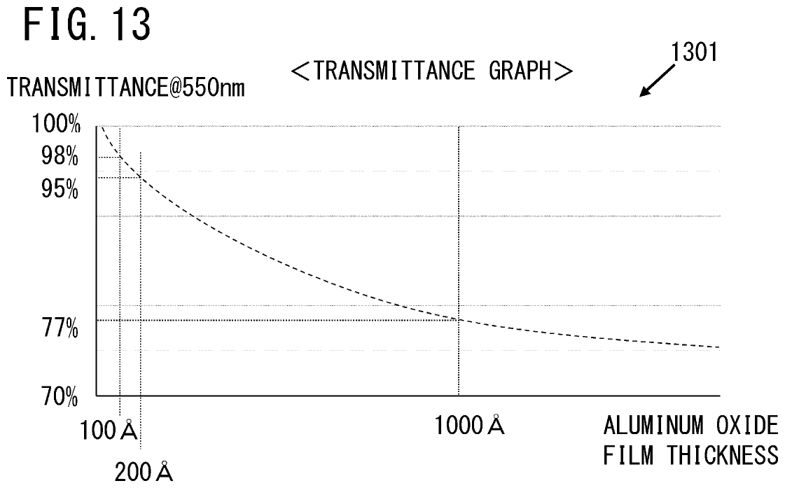

FIG. 13 is a graph 1301 showing the thickness of an aluminum oxide film, and the transmittance of the visible light (wavelength 550 nm) of the aluminum oxide film. The film thickness and the transmittance were measured by a commercially available transmission spectrometer.

The graph 1301 indicates as follows: when the film thickness is 100 Å, the transmittance is 98%, and the transmittance is hardly reduced; however, when the film thickness is 1000 Å, the transmittance is reduced to about 77%. The required value as a sensor is required to be, for example, a transmittance of at least 95%, and hence the film thickness is required to be suppressed to about 200 Å at most.

On the other hand, as described in conjunction with (1), a decrease in film thickness results in an increase in dark current, and hence the proper aluminum oxide film thickness has a restriction. However, this shall not apply to the case where the reduction of the transmittance is acceptable.

Fourthly, a description will be given to “(4) the relationship between the area of the photodiode interface and the dark current”.

The purpose for studying this relationship is because it is considered that dangling bonds are generated at the photodiode interface. Herein, a study has been conducted on four types of solid-state image pickup elements having different interface areas. The four types are as follows.

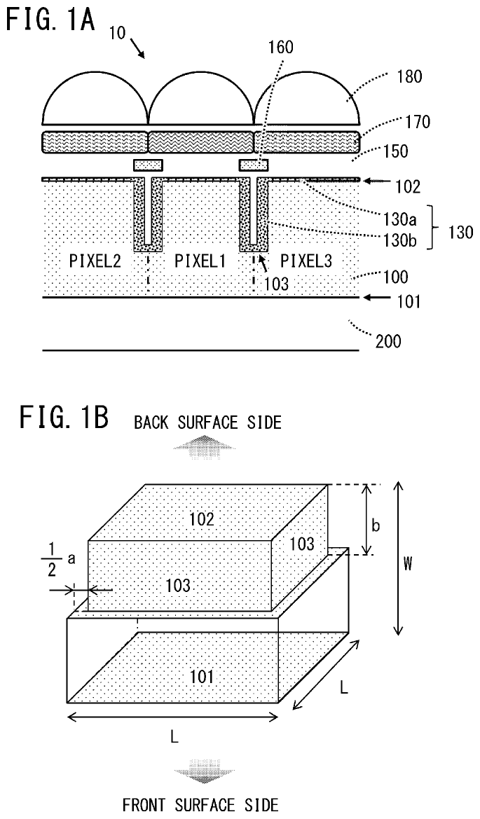

(A) Solid-state image pickup element in accordance with the present Embodiment . . . FIGS. 1A and 1B

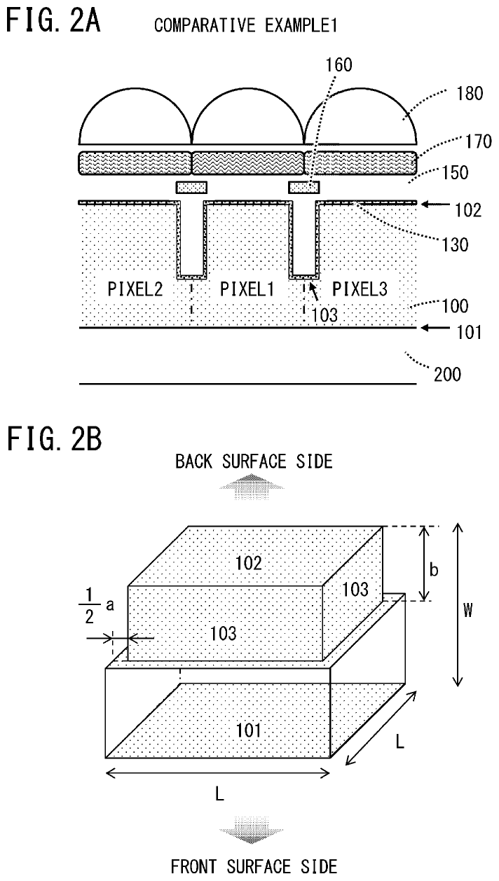

(B) Solid-state image pickup element disclosed in WO 2013/111628 . . . FIG. 2A and FIG. 2B

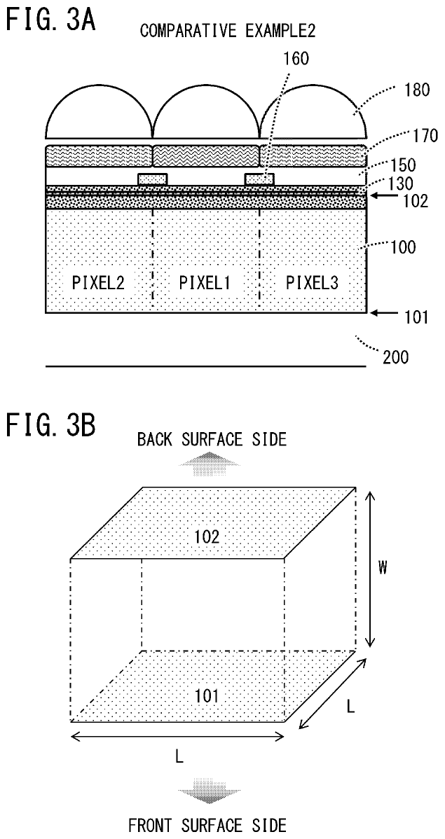

(C) Back side illumination type imaging element not having a back side trench structure . . . FIG. 3A and FIG. 3B

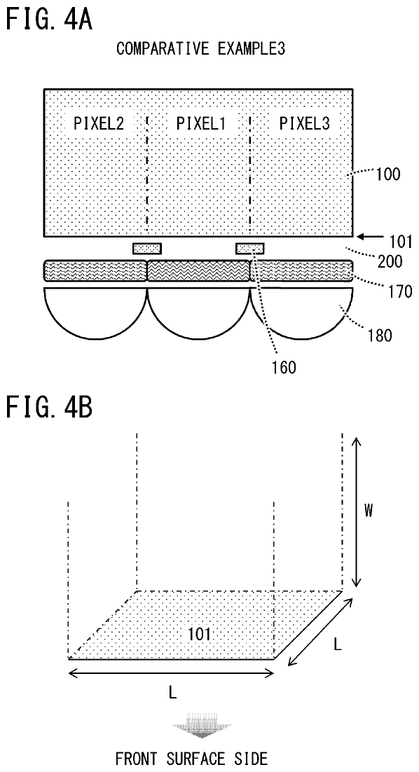

(D) Front side illumination type solid-state image pickup element . . . FIG. 4A and FIG. 4B

In FIGS. 1A to 4A, 100 represents a photodiode; 103, a trench (back side trench) disposed at the back surface of the photodiode 100; and 130, an aluminum oxide film disposed at the interface of the photodiode. The difference between the solid-state image pickup element (A) of FIG. 1A and the solid-state image pickup element (B) of FIG. 2A is in the thickness of the aluminum oxide film 130 formed at the back side trench part 103. The thickness of the aluminum oxide film 130 of the solid-state image pickup element (A) in accordance with the present Embodiment is larger than that of the solid-state image pickup element (B). Both of the solid-state image pickup elements (A) and (B) are equal in thickness of the aluminum oxide film 130 disposed at the surface in parallel with the back surface.

FIGS. 1B to 4B are each a simplified view obtained by stereoscopically capturing one photodiode of FIGS. 1A to 4A, and enabling calculation of the area of the interface at which the photodiode is in contact with other materials than silicon. Herein, L is the pixel size (length of one side), W is the pixel depth, a is the width of the back side trench, and b is the depth of the back side trench. For convenience, assuming that L=20 t, and W=10 t, it was configured such that comparison was enabled with the area of the interface of FIG. 4A as 100%. Further, it was configured such that a=t, and b=5 t.

A description will be given to the method for determining the area of the interface at which the photodiode is in contact with other materials. For the simplest front side illumination type solid-state image pickup element (D), the area of the interface is in agreement with the whole photodiode front surface part 101 hatched in FIG. 4B, and L²=20 t×20 t=400 t².

Then, for the back side illumination type solid-state image pickup element (C) not having a simple back side trench structure, the area of the interface is the total area of the photodiode front surface part 101 hatched in FIG. 3B and the photodiode back surface part 102, and 2×L²=800 t².

Similarly, for the imaging element (A) of the present Embodiment and the imaging element (B) of WO 2013/111628, the areas of interfaces are the areas of the hatched portions in FIGS. 1B and 2B, respectively. The area of the interface is the total value of the area of the photodiode front surface part 101, the area of the photodiode back surface part 102, and the area (the bottom surface and the side surface) of the back side trench part 103.

The summary of the interface areas of the imaging elements of respective types is the following table.

| | | | | | FS | BACK | BACK | |
|---|---|---|---|---|---|---|---|---|
| | | | | | SIDE | SURFACE | SURFACE | TOTAL |
| | L | W | a | b | AREA | PART AREA | TRENCH AREA | INTERFACE AREA |
| A | 20 t | 10 t | t | 5 t | 400 t² | 361 t² | 419 t² | 1180 t² (295%) |
| B | 20 t | 10 t | t | 5 t | 400 t² | 361 t² | 419 t² | 1180 t² (295%) |
| C | 20 t | 10 t | — | — | 400 t² | 400 t² | — | 800 t² (200%) |
| D | 20 t | 10 t | — | — | 400 t² | — | — | 400 t² (100%) |

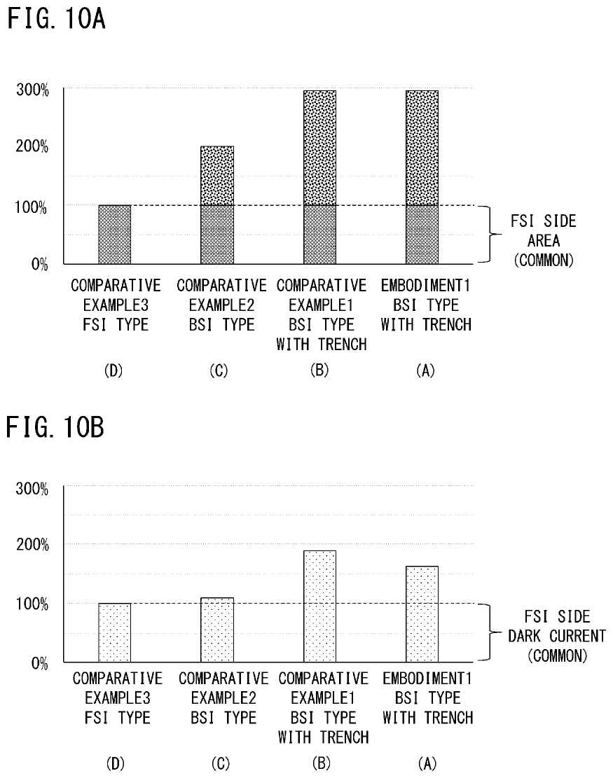

FIG. 10A is a view showing this table as a graph. Namely, the graph of FIG. 10A represents the area of the portion of the photodiode in contact with other materials in each solid-state image pickup element of four structures of FIGS. 1A to 4A.

FIG. 10B is a view showing the comparison graph of the dark current value in each solid-state image pickup element of four structures. Each dark current value of other solid-state image pickup elements when the dark current value of the front side illumination type solid-state image pickup element (D) is normalized to 100% is expressed in %. Incidentally, the data is the actual value obtained in the following manner: the present inventors manufactured solid-state image pickup elements of four structures by themselves, and measurement was performed for each resulting prototype as the object.

Comparison between FIG. 10A and FIG. 10B can indicate that adoption of a back side trench structure results in a rapid increase in dark current value. As for the solid-state image pickup element (C) not having a back side trench structure, the interface area increases, but the dark current value does not increase. As a result, it can be concluded that the dark current value and the interface area have no correlation.

Incidentally, strictly, the solid-state image pickup element also has a trench structure on the front surface side, which has a low impact in the study herein, and hence is regarded as a flat surface to be dealt with.

Fifthly, a description will be given to “(5) the estimation of the dark current value”.

The dark current can be estimated by the product of “the area of the interface at which a dark current is generated”, “the defect density at the interface”, and “the suppression rate of the dark current suppression part”. The study in conjunction with the item (4) has shown that “the area of the interface” less contributes, but, herein, is left as a variable. The dark current suppression parts may include a fixed electric charge film, surface recombination film, and the like. Below, the dark current is expressed as I; the area of the interface, as S; the defect density, as a; and the suppression rate of the dark current suppression part, as N.

The dark current value I (fs) of the front side illumination type solid-state image pickup element (Front Side Illumination) is as shown by the equation (1).

I(fs)=S(fs)×σ(fs)×N(fs) (1)

The units of respective variables are, for example, dark current I [pA], the area of the interface S [cm²], the interface defect density σ [number of defects/cm²], and the suppression rate of the dark current suppression part N [%].

The dark current value I (bs) of the back side illumination type solid-state image pickup element (Back Side Illumination) is as shown by the equation (2).

I(bs)=S(fs)×σ(fs)×N(fs)+S(bs)×σ(bs)×N(bs) (2)

S (fs)=S (bs), and hence the equation (2) can be modified to the equation (2)′.

I(fs)=S(fs)×{σ(fs)×N(fs)+σ(bs)×N(bs)} (2)′

With the study in conjunction with the item (4), for the back side illumination type imaging element without a back side trench structure, the dark current value has scarcely increased regardless of the fact that the interface area of the photodiode was doubled (see FIG. 10B). The reason for this is considered to be either or both of the fact that the defect density σ (bs) on the back surface side is low, or the fact that the dark current suppression rate N (bs) on the back surface side is high from the equation (2)′. However, from the study on the manufacturing procedure of the prototype, it is hard to consider that the defect density σ (bs) on the back surface side is remarkably smaller than the defect density σ (fs) on the front surface side. Therefore, it is presumed that the pinning effect N (bs) of the metal oxide film having a negative fixed electric charge deposited on the photodiode back surface side is large, and that the dark current suppression rate largely acts.

The dark current value I (T-bs) of the back side illumination type solid-state image pickup element (T-bs) having the back side trench structure (Trench) is as shown by the equation (3). Herein, the bs-surface means the photodiode back surface part, and the bs-trench means the back side trench inside.

$$I ( {T}_{bs} ) = S ( f s ) \times σ ( f s ) \times N ( fs ) + S ( b {s}_{surface} ) \times σ ( b {s}_{surface} ) \times N ( b {s}_{surface} ) + S ( {bs}_{trench} ) \times σ ( b {s}_{trench} ) \times N ( {bs}_{trench} ) \qquad ( 3 )$$

Herein, it can be regarded that S (fs)≈S (bs-surface)≈S (bs-trench). Although strictly different, the difference is sufficiently smaller than the order of the dark current to be argued, so that it does not matter if such approximation is performed.

Further, the metal oxide films having the negative fixed electric charge films with the same film thickness and of the same material are deposited in the silicon front surface part and inside the trench. Accordingly, the pinning suppression rates are the same. Namely, N (bs−surface)=N (bs−trench).

From the description up to this point, the equation (3) can be modified to the equation (3)′.

I(T_{bs})=S(fs)·{σ(fs)×N(fs)+σ(bs_{surface})×N(bs_{surface})+σ(bs_{trench})×N(bs_{trench})} (3)′

In the study of the item (4) (see the graph of FIG. 10B), two factors that can be considered as the reason why the dark current value increased to nearly two times when the back side trench structure was added will be mentioned below.

(Factor 1) The step added for back side trench formation (=photo/etching/resist release) caused a large number of defects at the photodiode back surface part. Namely, the value of a (bs-surface) has increased.

(Factor 2) The damage upon forming the back side trench caused a large number of defects inside the trench. As a result, the defect density σ (bs-trench) is larger than the a (bs-surface), and the N (bs-trench) with respect to this is insufficient.

The dark current value of the back side illumination type solid-state image pickup element having a back side trench structure in accordance with the present Embodiment is as shown in the equation (4).

$${I}^{′} ( {T}_{bs} ) = {S}^{′} ( fs ) \times {σ}^{′} ( fs ) \times {N}^{′} ( fs ) + {S}^{′} ( b {s}_{surface} ) \times {σ}^{′} ( b {s}_{surface} ) \times {N}^{′} ( b {s}_{surface} ) + {S}^{′} ( {bs}_{trench} ) \times {σ}^{′} ( b {s}_{trench} ) \times {N}^{′} ( {bs}_{trench} ) \qquad ( 4 )$$

At this step, the point that it can be regarded that S (fs)≈S′ (fs)≈S′ (bs-surface)≈S′ (bs-trench) is the same as described above. Further, the photodiode front surface is also the same as that of the related art example. For this reason, it holds that a (fs)=σ′ (fs), and that N (fs)=N′ (fs). Further, the film thickness of the metal oxide deposited at the photodiode back surface part is the same as that of the related art example. For this reason, it holds that N (bs-surface)=N′ (bs-surface). Further, the defect density inside the trench has the common point that damages are caused by etching formation as with the related art example. Accordingly, σ (bs-trench)=σ′ (bs-trench).

From the description up to this point, the equation (4) can be modified to the equation (4)′.

I′(T_{bs})=S(fs)·{σ(fs)×N(fs)+σ′(bs_{surface})×N(bs_{surface})+σ(bs_{trench})×N′(bs_{trench})} (4)′

In the study in conjunction with the item (4) (see the graph of FIG. 10B), the reason why the solid-state image pickup element (A) of the present Embodiment has a smaller dark current than that of the solid-state image pickup element (B) of the related art example even when both have the same back side trench structure is as follows.

From the equation (3)′ and the equation (4)′, the difference between I (T-bs) and I′ (T-bs) is expressed by the following equation (5).

I(T_{bs})−I′(T_{bs})=S(fs)·N(bs_{surface})·{σ(bs_{surface})−σ′(bs_{surface})}+S(fs)·σ(bs_{surface})·{N(bs_{trench})−N′(bs_{tranch})} (5)

The first term on the right side of the equation (5) represents the suppressing effect of the factor 1. In the present Embodiment, as described later, the damaged portion of the front surface is removed by CMP, or the like in “manufacturing method flow 7. additional back surface thinning step”. As a result, the factor 1, namely, a large number of defects are suppressed at the photodiode back surface part. For this reason, the relationship of σ (bs-surface)>σ′ (bs-surface) holds.

The second term on the right side of the equation (5) represents the suppressing effect of the factor 2. The solid-state image pickup element of the present Embodiment has a structure in which “the thickness of the metal oxide film to be deposited is larger inside the trench than at the front surface part”. As a result, the effect of the fixed electric charge film is enhanced (this point will be described in detail later), and the dark current suppression rate increases. For this reason, the relationship of N (bs−trench)>N′ (bs−trench) holds.

Thus, in the equation (5) representing the dark current value in each solid-state image pickup element in the present Embodiment and the related art example, the first term and the second term both assume positive values. This results in the relational expression of I (T−bs)>I′ (T−bs). Namely, this means that the solid-state image pickup element of the present Embodiment can more suppress the dark current as compared with the related art example.

The description up to this point is the effect estimation of the dark current suppression in the present Embodiment.

### Embodiment 1

FIG. 1A is a view showing the cross sectional structure of a solid-state image pickup element (photoelectric conversion device) 10 in accordance with Embodiment 1. The solid-state image pickup element 10 in accordance with the present Embodiment is a back side illumination type solid-state image pickup element in which a wiring layer is disposed on the opposite surface (front surface; the second surface) of a semiconductor substrate to the light receptive surface (back surface; the first surface).

As shown in FIG. 1A, a semiconductor substrate 100 is, for example, a silicon substrate, and includes a plurality of photoelectric converting parts for receiving light, and generating electric charges, formed therein. Further, a structure 200 is formed at the front surface part 101 of the semiconductor substrate 100, and a metal oxide film 130, a structure 150, a light shield wall 160, a color filter 170, and a microlens 180 are formed at the back surface part 102.

The semiconductor substrate 100 has a back side trench part 103 for separating pixels on the side of the light receptive surface (back surface). A metal oxide film 130 is disposed on the back surface part 102 of the semiconductor substrate 100 and the back side trench part 103 in the inside (at the side surface and the bottom surface) of the semiconductor substrate 100. The structure 150 on the back surface side includes an interlayer insulation film. The light shield wall 160 prevents the light passed through the microlens 180 from being made incident upon the adjacent pixel, and prevents optical color mixture. The structure 200 on the front surface side includes a wiring layer, an interlayer insulation film, and a circuit substrate.

Below, the metal oxide film formed at the back surface part 102 (the surface in parallel with the light receptive surface) of the semiconductor substrate 100 is referred to as a metal oxide film 130a, and the metal oxide film formed inside the back side trench part 103 is referred to as a metal oxide film 130b. The metal oxide film 130a corresponds to a first metal oxide film, and the metal oxide film 130b corresponds to a second metal oxide film. Further, the metal oxide film 130a and the metal oxide film 130b are collectively referred to as a metal oxide film 130.

As shown in FIG. 1A, in the solid-state image pickup element 10 of the present Embodiment, the film thickness of the metal oxide film 130b inside the back side trench part 103 is larger than the film thickness of the metal oxide film 130a at the back surface part 102.

A SiO₂ film (not shown) of a natural oxide film is formed with a thickness of about 50 Å between the semiconductor substrate 100 and the metal oxide film 130. The thickness of the oxide film can affect the effect of the fixed electric charge. As the value of the flat band potential shift ΔVfb increases, the dark current suppressing effect increases, with an increase in film thickness, hence a larger film thickness is desirable. However, a too small film thickness results in the contact between the fixed electric charge film and silicon, creating a risk of reducing the fixed electric charge. For this reason, the film thickness is desirably suppressed to a film thickness capable of controlling the risk. The thickness of the natural oxide film can be set at, for example, at least 25 Å and not more than 100 Å.

The material for the metal oxide film 130 is desirably a negative fixed electric charge film of aluminum oxide (alumina), hafnium oxide (hafnia), or the like. The reason for this is as follows: the defects caused upon processing the semiconductor substrate back surface part 102 become the factor for generating the dark current; in contrast, the fixed electric charge of the metal oxide film 130 has an effect of suppressing the dark current. When the metal oxide film 130 is an aluminum oxide film, the hydrogen concentration in the metal oxide film 130 is the value close to 10²¹ atoms/cm³. The material for the metal oxide film 130 may be zirconium oxide, tantalum oxide, or titanium oxide other than aluminum oxide or hafnium oxide. Incidentally, the metal oxide film 130a formed at the back surface part 102 of the semiconductor substrate 100, and the metal oxide film 130b formed inside the back side trench part 103 may include metal oxides having the mutually same composition, or may include metal oxides having different compositions.

The portion surrounded by the metal oxide film 130b in the back side trench part may be embedded with an embedding material. The embedding material is, for example, silicon oxide or silicon nitride. Provision of the embedding material can eliminate the hole inside the back side trench part 103, resulting in the improvement of the reliability.

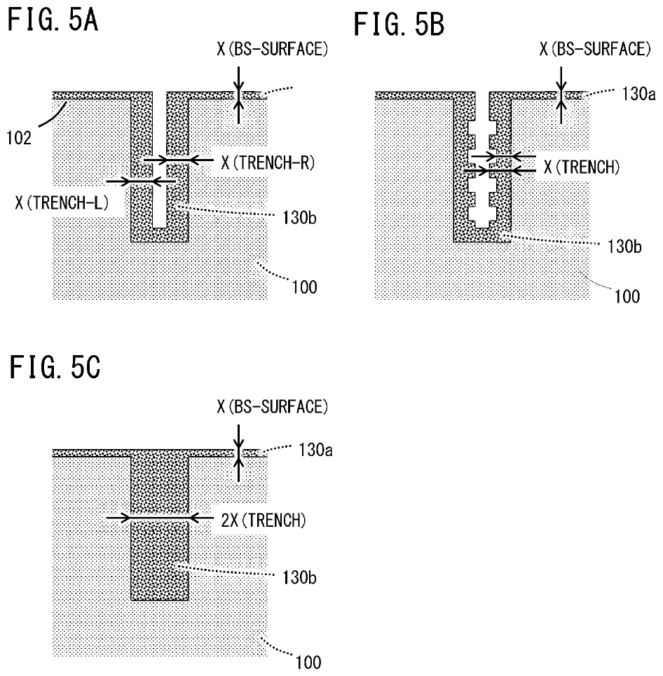

As already described, the dark current and the transmittance have a reciprocal relation, and hence, the metal oxide film 130a formed on the semiconductor substrate back surface part 102 has a restriction on the film thickness. Therefore, different uses must be employed depending upon requirements. On the other hand, the film thickness of the metal oxide film 130b formed inside the back side trench part 103 does not have the restriction. This is because an incident light does not pass through this portion. Therefore, inside the back side trench part 103, the film thickness of the metal oxide can be increased without restriction so long as it falls within the range allowing embedding in the trench for the dark current countermeasure. In FIG. 1A, the back side trench part 103 is not fully embedded with the metal oxide film 130b. However, as shown in FIG. 5C, the entire inside of the back side trench part 103 may be fully embedded with the metal oxide film 130b.

Referring to FIGS. 5A to 5C, a description will be given to the definition of the film thickness of the metal oxide film 130.

The film thickness of the metal oxide film 130 denotes the thickness in the direction perpendicular to the interface of the semiconductor substrate 100 (the direction of the normal to the interface). Specifically, as shown in FIG. 5A, the film thickness X (bs-surface) of the metal oxide film 130a on the semiconductor substrate back surface part 102 is the thickness in the direction perpendicular to the light receptive surface (the up direction in the drawing). The film thickness of the metal oxide film 130b inside the back side trench part 103 is the thickness in the direction perpendicular to the side surface of the back side trench part 103. The film thickness X (trench-L) of the trench left side surface is the film thickness in the direction perpendicular to the trench left side surface (the right direction in the drawing), and the film thickness X (trench-R) of the right side surface is the film thickness in the direction perpendicular to the trench right side surface (the left direction in the drawing).

As shown in FIG. 5B, the film thickness of the metal oxide film 130b inside the back side trench part 103 may vary at every position. In this case, the film thickness of the metal oxide film 130b can be grasped as the thickness of the thickest portion. Namely, the film thickness of the thickest portion of the metal oxide film 130b may only be larger than the film thickness of the metal oxide film 130a. Incidentally, the metal oxide film 130b inside the back side trench part 103 is desirably increased in film thickness, and hence intentional partial decrease in film thickness should be avoided.

On the metal oxide film 130, an antireflection film including a material with a higher refractive index than that of the metal oxide film 130 such as tantalum oxide may be formed. Namely, on the back surface part 102 of the semiconductor substrate 100, a plurality of metal oxide films having different compositions or characteristics (such as the refractive index, and the hydrogen concentration) may be formed. In such a case, the film thickness of the metal oxide film 130a is defined as not including the film thickness of the antireflection film.

The film thickness of the metal oxide film 130a can also be grasped as the thickness of the metal oxide film having a specific composition or characteristic, provided on a natural oxide film at the back surface part 102 of the semiconductor substrate 100, or closest to the interface of the back surface part 102 of the semiconductor substrate 100. Similarly, the film thickness of the metal oxide film 130b can also be grasped as the thickness of a metal oxide film having a specific composition or characteristic, provided on a natural oxide film at the back side trench part 103 side surface, or closest to the interface of the back side trench part 103. Further, the film thickness of the metal oxide film 130a on the semiconductor substrate back surface part 102 and the film thickness of the metal oxide film 130b inside the back side trench part 103 may be defined as the thicknesses of the metal oxide films having the mutually same composition or characteristic.

As described above, the film thickness of the metal oxide film 130b inside the back side trench part 103 is larger than the film thickness of the metal oxide film 130a of the back surface part 102. The thickness of the metal oxide film 130b is set at preferably at least twice, more preferably at least 5 times, and further preferably at least 10 times the thickness of the metal oxide film 130a. Further, the thickness of the metal oxide film 130b is preferably thicker than the thickness of the metal oxide film 130a by at least 100 Å, more preferably thicker by at least 500 Å, and further preferably thicker by at least 1000 Å. For example, the thickness of the metal oxide film 130a can be set at least 50 Å and not more than 200 Å, and the thickness of the metal oxide film 130b can be set at least 500 Å and not more than 2000 Å.

Further, when the film thickness of the metal oxide film 130b inside the back side trench part 103 varies according to the site as shown in FIG. 5B, the thickness of the metal oxide film 130b at the thickest part may only be larger than the thickness of the metal oxide film 130a.

A configuration can also be considered in which the entire inside of the back side trench part 103 is embedded with the metal oxide film 130 as shown in FIG. 5C. The film thickness of the metal oxide film 130b inside the back side trench part 103 in this case is defined as half of the trench width. According to such definition, the film thickness of the metal oxide film 130b being larger than the film thickness of the metal oxide film 130a can also be expressed as the width of the back side trench 130 being larger than twice the film thickness of the metal oxide film 130a.

Although a description has been given by way of specific examples up to this point, the scope of the present invention should not be construed as being limited to the specific examples. For example, the materials and the film thickness of the semiconductor substrate 100 or the metal oxide film 130 are not limited to the specific examples described above.

Thus, the metal oxide film 130b is thicker than the metal oxide film 130a. For this reason, as shown in FIG. 12A, the hydrogen concentration of the semiconductor substrate 100 in the region close to the metal oxide film 130b is higher than the hydrogen concentration of the semiconductor substrate 100 in the region close to the metal oxide film 130a.

Then, a method for manufacturing a solid-state image pickup element 10 will be described by reference to the accompanying drawings.

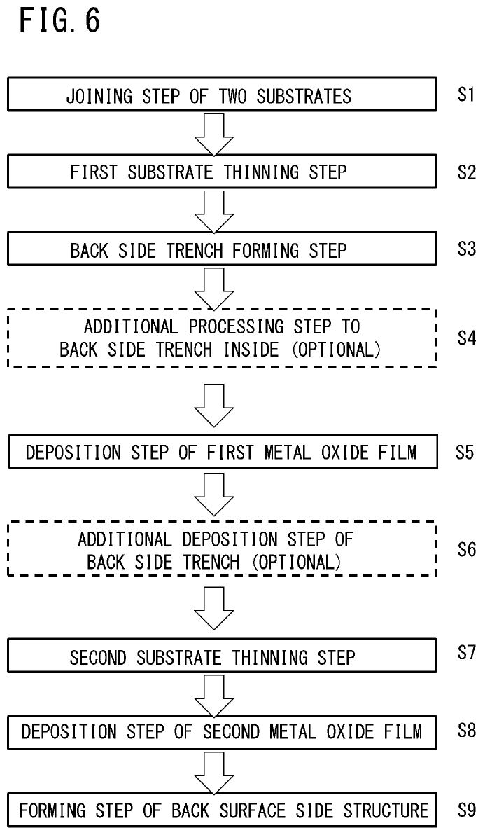

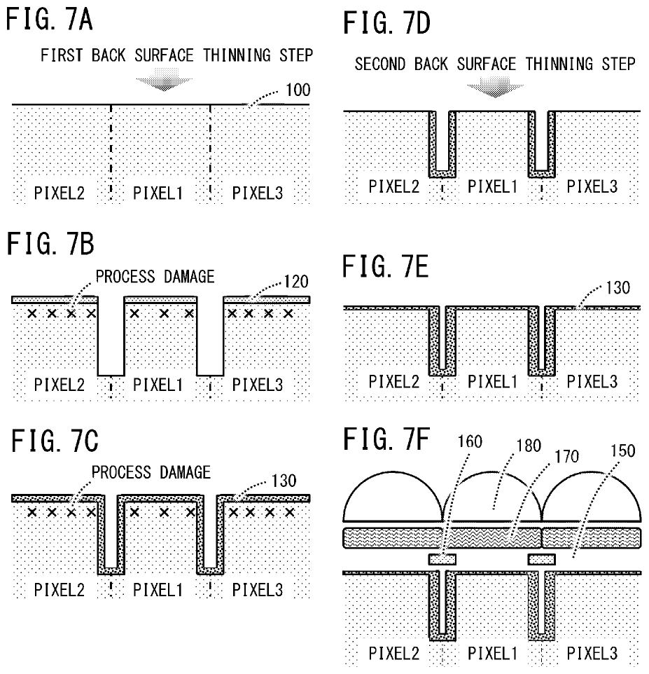

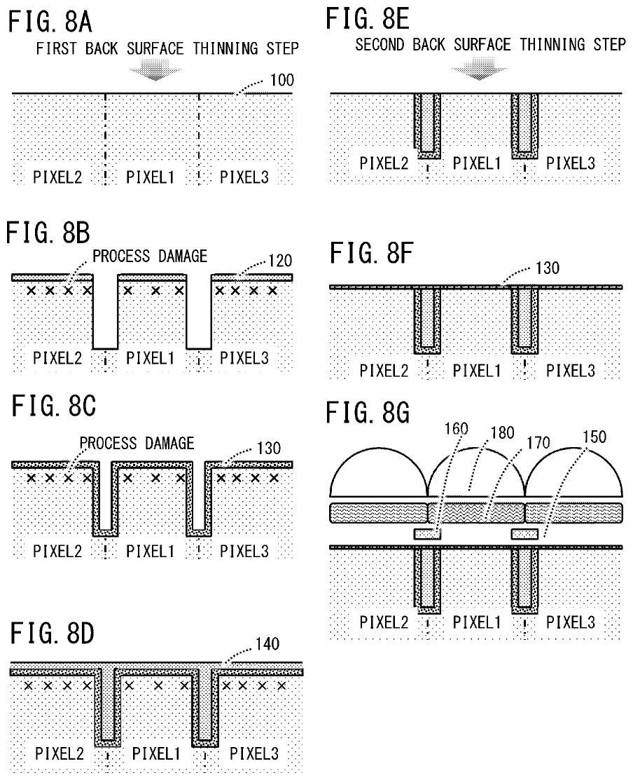

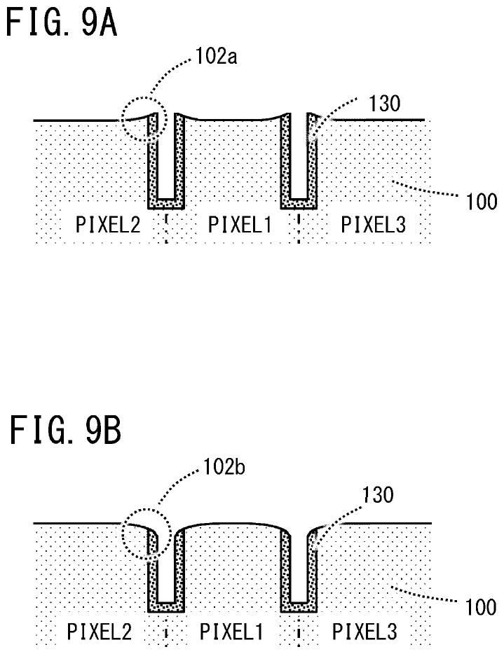

FIG. 6 is a process flowchart of the manufacturing method in accordance with the present Embodiment. In the drawing, the steps S4 and S6 indicated with dotted lines are omittable steps. FIGS. 7A to 7F are each a cross sectional view of each step when the step S6 is omitted. FIGS. 8A to 8G are each a cross sectional view of each step when the step S6 is adopted. FIGS. 9A and 9B are each a cross sectional schematic view of the back side trench after the second substrate thinning (CMP) step S7.

A description will be given according to the order of the process flowchart of FIG. 6.

### S1: Joining Step of Two Substrates

First, a substrate obtained by constructing a driving circuit transistor and metal wiring on an about 775 μm thick silicon wafer, and a substrate obtained by constructing a photoelectric converting part and metal wiring similarly on an about 775 μm thick silicon wafer are prepared. Then, the two substrates are bonded and joined with the metal wiring surfaces facing each other. As a result, mutual metal wirings are joined, which enables the photoelectric converting part to be controlled by the driving circuit transistor.

### S2: First Substrate Thinning Step

The light receptive surface side of the semiconductor substrate 100 is thinned with a known method (FIGS. 7A and 8A). Finally, thinning is performed to a thickness enough to allow a light from the back surface (light receptive surface) side to be sufficiently made incident upon the photoelectric converting part.

### S3: Trench Forming Step

A trench is formed on the back surface (light receptive surface) side of the semiconductor substrate 100 with a known method (FIGS. 7B and 8B). For example, an etching hard mask 120 is patterned on the back surface 102 of the semiconductor substrate 100, and a trench is formed by etching. After trench formation, the mask 120 is removed. Incidentally, in the present step, it is known that damages (e.g., damages due to etching) are caused in the semiconductor substrate back surface part 102 and the back side trench part 103. This is expressed as a mark “×” in the drawing. It is understood that the damage becomes an interface defect, which may cause a dark current.

### S4: Additional Processing to Trench Inside (Optional)

If required, the defect due to the damage caused in the previous step may be recovered by known hydrogen alloy or plasma doping.

### S5: Deposition Step of First Metal Oxide Film

With the atomic layer deposition method (ALD method), an aluminum oxide film 130 is deposited with a thickness of 1000 Å (FIGS. 7C and 8C). After deposition, annealing is performed within such a range of temperatures (300° C. to 400° C.) as not to cause electromigration of wiring, thereby activating the aluminum oxide film. In the present step, the inside of the back side trench part 103 may be fully embedded with the aluminum oxide film 130 or may not be fully embedded.

### S6: Additional Embedding Step of Trench Inside (Optional)

When the trench part 103 inside is not fully embedded with the aluminum oxide film 130, if required, the portion surrounded by the aluminum oxide film 130 in the trench part 103 is embedded with an embedding material 140 such as silicon oxide (SiO) or silicon nitride (SiN) (FIG. 8D). As a result, the hole inside the trench part 103 can be eliminated, or reduced in size, thereby inhibiting the problem of reduction of the reliability.

### S7: Second Substrate Thinning Step

A second thinning treatment is carried out using CMP or the like until the thickness of the semiconductor substrate 100 becomes a desirable thickness (FIGS. 7D and 8E). For example, thinning is performed until the semiconductor substrate 100 comes to have a thickness of 3 μm.

When CMP is carried out in the present step, a specific shape may appear in the silicon back surface part 102 and the back side trench part 103 due to the difference in polishing rate caused by the difference between the material of the silicon back surface part 102 and the material of the embedding material 140 or the metal oxide film 130b. Specifically, the angle formed between the back surface part 102 (light receptive surface) in the vicinity of the back side trench part 103 and the side surface of the back side trench part 103 of the semiconductor substrate 100 becomes a different angle from a right angle.

For example, when the embedding material 140 of the back side trench is harder than the silicon back surface part 102, as shown in FIG. 9A, the silicon back surface part 102 rises in the vicinity 102a of the back side trench part 103. Namely, the height (thickness) of the silicon back surface part 102 becomes higher (thicker) with approach toward the back side trench part 103. This is because the periphery of a hard back side trench embedding material 140 remains, and the silicon back surface part 102 is cut, thereby causing dishing.

Further, conversely, when the embedding material 140 of the back side trench is softer than the silicon back surface part 102, as shown in FIG. 9B, the silicon back surface part 102 sinks at the vicinity 102b of the back side trench part 103. Namely, the height (thickness) of the silicon back surface part 102 becomes lower (thinner) with approach toward the back side trench part 103.

Herein, a description has been given by taking the case where the back side trench part 103 is embedded with the embedding material 140 as an example. However, even when the embedding material 140 is not provided, the same shape may appear due to the difference in polishing rate between the metal oxide film 130b and the back side trench part 103.

With a related art method, at the first substrate thinning step S2, first, the substrate is subjected to a thinning treatment until a desirable thickness is achieved. In contrast, in the present Embodiment, first, a trench is formed. Then, the substrate is subjected to a thinning treatment until a desirable thickness is achieved. With this method, the defects (expressed as mark “×” in the drawing) of the silicon back surface part due to the damages upon back side trench formation are removed. As a result, the dark current is reduced.

### S8: Deposition Step of Second Metal Oxide Film

After the second substrate thinning step S7, aluminum oxide is deposited with a thickness of 100 Å inside the silicon back surface part 102 and the back side trench part 103 by the ALD method (FIGS. 7E and 8F). The film thickness of the metal oxide film deposited in the second deposition step S8 may be set smaller than the film thickness of the metal oxide film deposited in the first deposition step S5. After deposition, annealing is performed within such a range of temperatures (300° C. to 400° C.) as not to cause electromigration of wiring, thereby activating the aluminum oxide film. Herein, the metal oxide film with the same composition as that of the first deposition step S5 is deposited. However, the metal oxide film with a different composition from that of the first deposition step S5 may be deposited.

### S9: Forming Step of Back Surface Side Structure

On the aluminum oxide film 130, structures necessary for fulfillment of functions of the solid-state image pickup element such as a light shield wall 160, a color filter 170, and a microlens 180 are formed with a known method.

By the steps up to this point, the solid-state image pickup element (photoelectric conversion device) can be manufactured.

### Embodiment 2

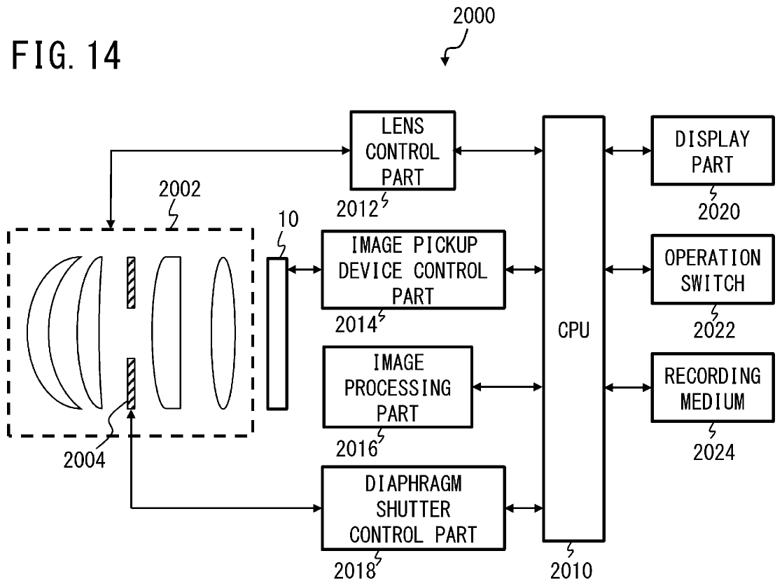

An imaging system in accordance with Embodiment 2 of the present invention will be described by reference to FIG. 14. FIG. 14 is a block view showing a schematic configuration of an imaging system in accordance with the present Embodiment.

The solid-state image pickup element (photoelectric conversion device) described in Embodiment 1 is applicable to various imaging systems. The applicable imaging system has no particular restriction, and examples thereof may include various devices such as a digital still camera, a digital camcorder, a surveillance camera, a copier, a fax, a portable phone, an onboard camera, an observation satellite, and a medical camera. Further, a cameral module including an optical system such as a lens and a solid-state image pickup element (photoelectric conversion device) is also included in the imaging system. FIG. 14 shows a block view of a digital still camera as one example thereof.

An imaging system 2000 includes, as shown in FIG. 14, an image pickup device 10, an image pickup optical system 2002, a CPU 2010, a lens control part 2012, an image pickup device control part 2014, an image processing part 2016, and a diaphragm shutter control part 2018. The imaging system 2000 further includes a display part 2020, an operation switch 2022, and a recording medium 2024.

The image pickup optical system 2002 is an optical system for forming an optical image of a subject, and includes a lens group, a diaphragm 2004, and the like. The diaphragm 2004 has a function of performing light amount adjustment by adjusting the aperture diameter, and additionally, also has a function as an exposure time adjusting shutter during photographing a still picture. The lens group and the diaphragm 2004 are held to be able to advance and retreat along the optical axis, and the linked operation thereof implements the scaling function (zooming function) and the focus adjusting function. The image pickup optical system 2002 may be integrated with the imaging system, or may be an image pickup lens mountable on the imaging system.

The image pickup device 10 is positioned so that the image pickup surface is situated in the image space of the image pickup optical system 2002. The image pickup device 10 is the solid-state image pickup element (photoelectric conversion device) described in Embodiment 1, and includes a CMOS sensor (pixel part) and the peripheral circuit (peripheral circuit region) thereof. For the image pickup device 10, pixels having a plurality of photoelectric converting parts are positioned two dimensionally, and color filters are positioned with respect to the pixels, thereby forming a two dimensional single plate color sensor. The image pickup device 10 photoelectrically converts the subject image formed by the image pickup optical system 2002, and outputs it as an image signal or a focus detection signal.

The lens control part 2012 is for controlling the advancing/retreating driving of the lens group of the image pickup optical system 2002, and performing a scaling operation and focus adjustment, and includes a circuit and a processing device configured so as to implement the functions. The diaphragm shutter control part 2018 is for changing the aperture diameter of the diaphragm 2004 (with the diaphragm value as variable), and adjusting the photographing light amount, and includes a circuit and a processing device configured so as to implement the functions.

The CPU 2010 is a control device in a cameral for governing various controls of the camera main body, and includes an operation part, a ROM, a RAM, an A/D converter, a D/A converter, a communication interface circuit, and the like. The CPU 2010 controls the operation of each part in the camera according to the computer program stored in the ROM or the like, and executes a series of photographing operations such as AF, image pickup, image processing, and recording including the detection of the focus state (focus detection) of the image pickup optical system 2002. The CPU 2010 is also a signal processing part.

The image pickup device control part 2014 is for controlling the operation of the image pickup device 10, and A/D converting the signal outputted from the image pickup device 10, and sending it to the CPU 2010, and includes a circuit and a control device configured so as to implement the functions. It does not matter if the A/D converting function is possessed by the image pickup device 10. The image processing part 2016 is a processing device for performing image processing such as y conversion or color interpolation on the A/D-converted signal, and generating an image signal, and includes a circuit and a control device configured so as to implement the functions. The display part 2020 is a display device such as a liquid crystal display device (LCD), and displays the information on the photographing mode of a camera, a preview image before photographing, a confirming image after photographing, the focused state upon focus detection, and the like. The operation switch 2022 includes a power supply switch, a release (shooting trigger) switch, a zooming operation switch, a shooting mode selecting switch, and the like. The recording medium 2024 is for recording the photographed image or the like, and may be the one included in the imaging system, or may be the detachable one such as a memory card.

The imaging system 2000 to which the solid-state image pickup element in accordance with Embodiment 1 is applied is configured in this manner. As a result, a high performance imaging system can be implemented.

### Embodiment 3

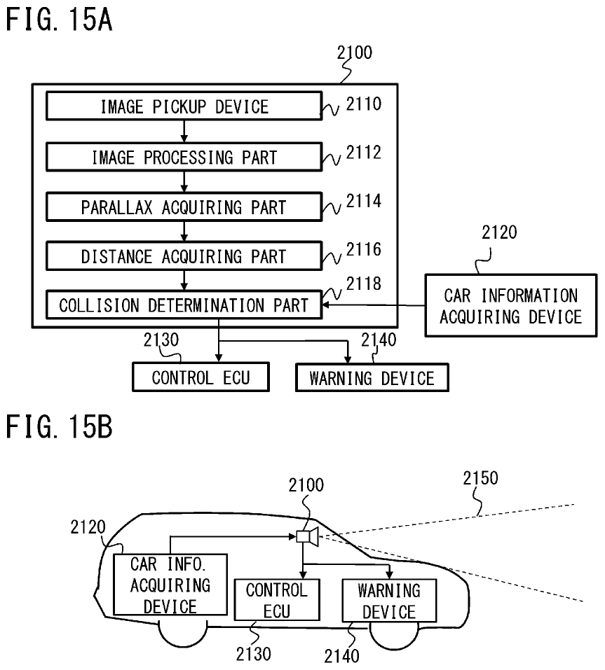

An imaging system and a mobile unit in accordance with Embodiment 3 of the present invention will be described by reference to FIGS. 15A and 15B. FIGS. 15A and 15B are views showing the configuration of the imaging system and the mobile unit in accordance with the present Embodiment.

FIG. 15A shows one example of an imaging system 2100 regarding an onboard camera. The imaging system 2100 has an image pickup device 2110. The image pickup device 2110 is any of the solid-state image pickup elements (photoelectric conversion devices) described in Embodiment 1. The imaging system 2100 has an image processing part 2112 and a parallax acquiring part 2114. The image processing part 2112 is a processing device for performing image processing on a plurality of image data acquired by the image pickup device 2110. The parallax acquiring part 2114 is a processing device for performing calculation of the parallax (phase contrast between parallax images) from the plurality of image data acquired by the image pickup device 2110. Further, the imaging system 2100 has a distance acquiring part 2116 which is a processing device for calculating the distance to the object based on the calculated parallax, and a collision determination part 2118 which is a processing device for determining whether there is a collision possibility or not based on the calculated distance. Herein, the parallax acquiring part 2114 or the distance acquiring part 2116 is one example of the information acquiring means for acquiring the information such as the distance information to the object. Namely, the distance information is the information regarding the parallax, the defocus amount, the distance to the object, or the like. A collision determination part 2118 may determine the collision possibility using any of the distance information. The processing devices may be implemented by an exclusively designed hardware, or may be implemented by a general-purpose hardware for performing operation based on a software module. Further, the processing device may be implemented by a FPGA (Field Programmable Gate Array), an ASIC (Application Specific Integrated Circuit), or the like, or may be implemented by the combination thereof.

The imaging system 2100 is connected to a car information acquiring device 2120, and can acquire car information such as the car speed, the yaw rate, or the steering angle. Further, to the imaging system 2100, a control ECU 2130 which is a control device for outputting a control signal for causing a car to generate a braking power based on the determination result of the collision determination part 2118. Namely, the control ECU 2130 is one example of the mobile unit control means for controlling the mobile unit based on the distance information. Further, the imaging system 2100 is also connected to a warning device 2140 for issuing a warning to a driver based on the determination results at the collision determination part 2118. For example, when the collision possibility is high as the determination result of the collision determination part 2118, the control ECU 2130 performs car control of applying brakes, releasing the accelerator, suppressing the engine output, or the like, thereby avoiding collision, and reducing the damage. The warning device 2140 sounds a warning such as a sound, displays warning information on a screen of a car navigation system, or the like, applies a vibration to a seat belt or a steering, and performs other operations, thereby giving a warning to a user.

In the present Embodiment, the periphery, for example, the front or the rear of the car is imaged by the imaging system 2100. FIG. 15B shows the imaging system 2100 when the car front (imaging region 2150) is imaged. The car information acquiring device 2120 sends instructions so as to operate the imaging system 2100 to execute image pickup. By using the solid-state image pickup element of Embodiment 1 as the image pickup device 2110, the imaging system 2100 of the present Embodiment can be more improved in precision of the distance measurement.

In the description up to this point, a description has been given to the example in which control is performed so as to prevent the collision with other cars. However, the present invention is applicable to the control of performing autonomous driving following another car, control of performing autonomous driving so as not to depart from the lane, and the like. Further, the imaging system is applicable to a mobile unit (transportation equipment) such as a ship, an aircraft, or an industrial robot not limited to a car such as an automobile. Mobile devices in the mobile unit (transportation equipment) are various driving sources such as an engine, a motor, a wheel, and a propeller. In addition, the present invention is applicable to, not limited to the mobile units, devices widely using object recognition such as the intelligent transport system (ITS).

In accordance with the present invention, it is possible to suppress the deterioration of the pixel performance in a photoelectric conversion device having a back side trench structure.

### OTHER EMBODIMENTS

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2020-065792, filed on Apr. 1, 2020, which is hereby incorporated by reference herein in its entirety.

What is claimed is:

1. A photoelectric conversion device having a wiring layer on an opposite side of a semiconductor substrate to a light receptive surface thereof, the device comprising:
a semiconductor substrate having a trench part on a side of the light receptive surface;
a first metal oxide film arranged at the light receptive surface of the semiconductor substrate; and
a second metal oxide film arranged at a side surface of the trench part and having a film thickness larger than that of the first metal oxide film.

2. The photoelectric conversion device according to claim 1, wherein a hydrogen concentration in the semiconductor substrate close to the second metal oxide film is higher than a hydrogen concentration in the semiconductor substrate close to the first metal oxide film.

3. The photoelectric conversion device according to claim 1, wherein the first metal oxide film is a film formed of a metal oxide with a first composition arranged on a natural oxide film at the light receptive surface of the semiconductor substrate.

4. The photoelectric conversion device according to claim 1, wherein the first metal oxide film and the second metal oxide film are formed of metal oxides of mutually same compositions.

5. The photoelectric conversion device according to claim 1, wherein the first metal oxide film and the second metal oxide film are any of aluminum oxide, zirconium oxide, tantalum oxide, and titanium oxide.

6. The photoelectric conversion device according to claim 1, wherein an embedding material is arranged in a portion surrounded by the second metal oxide film in the trench part.

7. The photoelectric conversion device according to claim 6, wherein the embedding material is silicon nitride or silicon oxide.

8. The photoelectric conversion device according to claim 1, wherein an angle formed between the light receptive surface in the vicinity of the trench part and the side surface of the trench part in the semiconductor substrate is not a right angle.

9. The photoelectric conversion device according to claim 8, wherein the light receptive surface in the vicinity of the trench part in the semiconductor substrate rises more with increasing approach to the trench part.

10. The photoelectric conversion device according to claim 8, wherein the light receptive surface in the vicinity of the trench part in the semiconductor substrate sinks more with increasing approach to the trench part.

11. An imaging system comprising:
the photoelectric conversion device according to claim 1; and
a signal processing part for processing a signal outputted from the photoelectric conversion device.

12. A mobile unit comprising:
the photoelectric conversion device according to claim 1;
a mobile device;
a processing device for acquiring information from a signal outputted from the photoelectric conversion device; and
a control device for controlling the mobile device on the basis of the information.

13. A photoelectric conversion device having a wiring layer on an opposite side of a semiconductor substrate to a light receptive surface thereof, the device comprising:
a semiconductor substrate having a trench part on a side of the light receptive surface;
a first metal oxide film arranged at the light receptive surface of the semiconductor substrate; and
a second metal oxide film embedded in the trench part, wherein
a width of the trench part is larger than twice a film thickness of the first metal oxide film.

14. The photoelectric conversion device according to claim 13, wherein the first metal oxide film is a film formed of a metal oxide with a first composition arranged on a natural oxide film at the light receptive surface of the semiconductor substrate.

15. The photoelectric conversion device according to claim 13, wherein the first metal oxide film and the second metal oxide film are formed of metal oxides of mutually same compositions.

16. The photoelectric conversion device according to claim 13, wherein the first metal oxide film and the second metal oxide film are any of aluminum oxide, zirconium oxide, tantalum oxide, and titanium oxide.

17. An imaging system comprising:
the photoelectric conversion device according to claim 13; and
a signal processing part for processing a signal outputted from the photoelectric conversion device.

18. A mobile unit comprising:
the photoelectric conversion device according to claim 13;
a mobile device;
a processing device for acquiring information from a signal outputted from the photoelectric conversion device; and
a control device for controlling the mobile device on the basis of the information.

19. A manufacturing method for a photoelectric conversion device, the method comprising:
a trench forming step of forming a trench part at a first surface of a semiconductor substrate;
a first deposition step of depositing a metal oxide film at the first surface, and a side surface of the trench part of the semiconductor substrate;
a thinning step of thinning the first surface of the semiconductor substrate after the first deposition step; and
a second deposition step of depositing a metal oxide film at least on the first surface of the semiconductor substrate after the thinning step.

20. The manufacturing method for a photoelectric conversion device according to claim 19, wherein a film thickness of the metal oxide film deposited in the second deposition step is smaller than a film thickness of the metal oxide film deposited in the first deposition step.
